(19) United States
(12) Patent Application Publication
(10) Pub. No.: US 2011/0002375 A1
(43) Pub. Date: Jan. 6, 2011

(54) Information reproducing apparatus using adaptive equalizer and adaptive equalization method

(75) Inventor: Hiromi Honma, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Renesas Electronics Corporation, Kawasaki (JP)

(21) Appl. No.: 12/801,583

(22) Filed: Jun. 15, 2010

(30) Foreign Application Priority Data
Jul. 2, 2009 (JP) 2009-157562

(51) Int. Cl. H03K 5/159

(52) U.S. Cl. 375/232

(57) ABSTRACT

An adaptive equalizer includes: an equalizer configured to equalize a digital RF signal based on a plurality of tap coefficients; and a tap coefficient controller configured to correct the plurality of tap coefficients in a time division. The tap coefficient controller includes a tap coefficient register configured to hold the plurality of tap coefficients; and a product-sum calculating circuit configured to correct at least one selected from the plurality of tap coefficients in response to an enable signal, by a predetermined product-sum calculation, and update the selected tap coefficient by the corrected tap coefficient.

### INCORPORATION BY REFERENCE

This patent application claims a priority on convention based on Japanese Patent Application No. 2009-157562 filed on Jul. 2, 2009. The disclosure thereof is incorporated herein by reference.

### TECHNICAL FIELD

The present invention relates to an adaptive equalizer, an information reproducing device, and an adaptive equalization method.

### BACKGROUND ART

Through recent development of a multimedia technique, a large amount of data including video data should be processed. Further, a capacity of a storage device for recording such data should be increased, and in particular, in the field of storage for high quality video data, BD (Blu-ray Disc) having a storage capacity far exceeding that of DVD (Digital Versatile Disc) is beginning to be put into the market. In order to increase a storage capacity of an optical disc or HDD device, a record density should be increased, and along with this, a reduction in an error rate and ensuring of reliability have become important issues.

On the other hand, if the record density of the optical disc is increased, a waveform obtained from the disc at a specific time interferes with that obtained from the disc at another time (this is referred to as intersymbol interference), and therefore reproduction of a short record mark of a certain length or less becomes difficult. On the other hand, if the record mark is long, an output frequency of phase data for extracting a synchronization clock is reduced, which causes step-out of synchronization. Accordingly, a length of the record mark should be limited to a predetermined length or less. For the above reasons, record data on the optical disc is encoded and recorded. In particular, an RLL code (Run Length Limited Code) in which a code inversion length is limited is often used, and a 17PP modulation code, EFM (Eight to Fourteen Modulation), 8/16 modulation core, and the like are used.

As a method for eliminating the intersymbol interference, a technique called waveform equalization is known. This is a method in which an error rate is reduced with an inverse filter eliminating the intersymbol interference. In the waveform equalization, a high frequency bandwidth component of a reproduction signal is enhanced to suppress the intersymbol interference. However, a high frequency bandwidth component of noise is also enhanced, and therefore an SNR (Signal to Noise Ratio) of the reproduction signal may be degraded. In particular, in a case of increasing the record density, the degradation in SNR due to the waveform equalization becomes a main cause of error in detection data.

On the other hand, PR (Partial Response) equalization is known that is one of waveform equalization methods, and intentionally gives rise to known intersymbol interference. According to the PR equalization, the degradation in SNR can be suppressed without enhancing the high frequency bandwidth component upon waveform equalization.

Meanwhile, as an effective detection method, a maximum likelihood detection method is known. In this method, detection performance is increased by selecting one having a minimum square mean error from among all possible time-series patterns for a data stream in which occurrence of a state transition is known. However, it is difficult to perform the above processing in an actual circuit from the viewpoint of a circuit size and an operation speed. For this reason, typically, the maximum likelihood detection method is realized by using algorithm called a Viterbi algorithm to recursively select a path. The maximum likelihood detection method using the Viterbi algorithm is referred to as Viterbi decoding or Viterbi detection.

A detection method in which the PR equalization and the Viterbi detection are combined is referred to as a PRML (Partial Response Maximum Likelihood) method. In a reproduction waveform after the PR equalization, only a specific state transition appears because of the PR equalization and modulation restriction. By using this to select a state transition path that minimizes the square mean error, the detection data error can be reduced. In particular, it is known that a code having the minimum run length of 1, such as the 17PP modulation code, and the PR equalization are fit with each other, and therefore a large detection margin can be obtained upon reproduction from a high record density of disc.

In order to increase the detection performance by the Viterbi detection, a frequency characteristic of a reproduction channel should be made to match to a characteristic of specific PR equalization such as PR (3, 4, 4, 3). In such a case, the PR equalization characteristic as close to the frequency characteristic of the reproduction channel as possible are selected. However, in the field of an optical disc, which handles replaceable media, a frequency characteristic of a reproduction signal is not unique. Also, the characteristics are changed due to degradation of an optical pickup, lens stain, or the like. For this reason, as a technique for adaptively correcting the frequency characteristic to increase the detection performance, an automatic equalization or adaptive equalization method is required. As an adaptive equalization algorithm of a sequential type, in particular, a Zero Forcing Method, Mean Square Method, or the like is typically used.

FIG. 1 illustrates a configuration example of a typical adaptive equalizer 200. The adaptive equalizer 200 is provided with an equalizer 1, a maximum likelihood detecting circuit 2, an equalization error generating circuit 3, delay circuits 9a to 9e, and correlating circuits 8a to 8e. The equalizer 1 is a typical N-tap FIR (Finite Impulse Response) filter. It is assumed that an input (digitalized RF signal drf) at time Ti is Xi, and each tap coefficient is αⱼ (j is an integer from 0 to N−1), an output (equalized signal eqo) Yi of the equalizer 1 is expressed by the following equation (1):

$$Yi = {\sum }_{j = 0}^{N - 1} {X}_{i - j} * {α}_{j} \qquad ( 1 )$$

where the number of taps is N.

The RF signal drf (Xi) that has been quantized in advance by an A/D converter of around 8 bits is equalized to a certain PR characteristic by the equalizer 1, and outputted to the maximum likelihood detecting circuit 2 and the equalization error generating circuit 3 as the equalized signal eqo. The maximum likelihood detecting circuit 2 detects a binary data sequence Do from the equalized signal eqo. For example, the maximum likelihood detecting circuit 2 outputs, as the binary data sequence Do, data detected from the equalized signal eqo on the basis of the Viterbi detection. The equalization error generating circuit 3 calculates an ideal value Ri of an input to the maximum likelihood detecting circuit 2 on the basis of the binary data sequence Do, and outputs a difference between the actual input (equalized signal eqo (Yi)) and the ideal value Ri as an equalization error err (ei). The equalization error (ei) is expressed by the following equation (2):

ei=Yi−Ri (2)

Further, a power P of the equalization error ei can be expressed by the following equation (3), which forms a superquadric surface with respect to the N-dimensional tap coefficient αⱼ:

$$P = {\sum }_{i = 0}^{M} {ei}^{2} \qquad ( 3 )$$

Accordingly, by correcting the tap coefficient αⱼ in the direction of −grad P=(−∂P/α₀, −∂P/α₁, . . . , −∂P/α_{N-1}), a minimum point of P is obtained. That is, given that a j^{th} tap coefficient value at the time Tᵢ is αⱼⁱ, the adaptive equalization can be achieved by the sequential correction:

αⱼⁱ⁺¹=αⱼⁱ−Δ∂P/αⱼ=αⱼⁱ−α′Xᵢ₋ⱼ*ei (4)

In order to realize the above equation (4) by use of a circuit, equalizer inputs Xᵢ₋ⱼ respectively having different phases are generated by the delay circuits 9a to 9e. Further, the correlation between Xᵢ₋ⱼ and the equalization error Ri is calculated by the correlating circuits 8a to 8e, and a result of the calculation is fed back to the equalizer 1 as tap coefficients α₀ to α₄. Thus, all of the prepared tap coefficients α₀ to α₄ are sequentially corrected, and after a certain time has passed, the tap coefficients α₀ to α₄ are converged. Each of the correlating circuits 8a to 8e includes a multiplier, an integrator (adder), and a delay circuit. Typically, correlating circuits for the number of the taps N are required in the equalizer 1.

FIG. 2 is a timing chart illustrating clock timing at the time of adaptive equalization operation in the conventional technique, and variation timings of the respective tap coefficients. Referring to FIG. 2, in the conventional technique, the correlating circuits for the number of the taps N (five in this case) are present, and therefore all of the tap coefficients α₀ to α₄ are sequentially corrected every one clock. For example, at time T1, α₀⁰ to α₄⁰ are corrected to α₀¹ to α₄¹.

Meanwhile, a reproduction signal from a disc recorded in a higher density receives larger influence of the intersymbol interference. For example, it may be influenced by data that is present a ten and a few channel clocks away from a sampling point. In order to adaptively equalize such a signal, the order of the FIR filter (the number of the taps in the equalizer) should be increased. That is, in order to reduce the influence of the intersymbol interference, the number of correlating circuits should be increased, each of which includes multipliers and integrators requiring large circuit areas. Further, if, in order to achieve a high speed read in association with high density recording, parallel processing is performed, the number of correlating circuits should be further increased. The increase in the number of circuits causes not only a cost increase in association with an increase in die size of an LSI but many problems such as a reduction in yield, increase in test time, and increase in power consumption.

In this context, a method for reducing a circuit amount with respect to parallel processing is described in patent literature 1. FIG. 3 is a diagram illustrating a configuration of an adaptive equalizer described in the patent literature 1. Referring to FIG. 3, the adaptive equalization circuit is provided with two transversal filters 10a and 10b, tentative discriminators 11a and 11b, switches 12 and 13, a correlator group 14, and a control signal generator 15. A synchronized reproduction signal is distributed into even-numbered values and odd-numbered values, which are separately inputted to the equalizers 10a and 10b. The tentative discriminators 11a and 11 b respectively output equalization errors corresponding to outputs from the two equalizers 10a and 10b. The transversal filters 10a and 10b use the common correlator group 14 on the basis of switching operation by the switches 12 and 13. At this time, the switches 12 and 13 are controlled by the control signal generator 15. Thus, the number of correlators is a half of the total number of taps in the transversal filters 10a and 10b.

Also, patent literature 2 proposes a method of performing synchronization at a lower rate than a channel rate to perform equalization, and restores an output of the equalization to channel rate synchronization timing by interpolation to perform maximum likelihood detection. In the patent literature 2, on the basis of this method, an increase in the number of circuits in association with an increase in speed can be suppressed.

### Citation List

### Patent Literature 1: JP 2004-79013A

### Patent Literature 2: JP 2008-181583A

### SUMMARY OF THE INVENTION

The method described in the patent literature 1 is effective if there are a plurality of equalization filters. However, the correlator group 14 itself cannot be decreased in size. Also, even by the method described in the patent literature 2, a correlator group itself cannot be decreased in size. In particular, in the case of a reproduction signal from a disc recorded in a high density, the number of taps increases, and in proportion to the increase, the correlator group is also increased in size.

In an aspect of the present invention, an adaptive equalizer includes: an equalizer configured to equalize a digital RF signal based on a plurality of tap coefficients; and a tap coefficient controller configured to correct the plurality of tap coefficients in a time division.

In another aspect of the present invention, an information reproducing apparatus includes: an A/D (analog-to-digital) converter configured to convert a reproduction signal read from an information storage medium into a digital RF signal; an adaptive equalizer which includes: an equalizer configured to equalize the digital RF signal based on a plurality of tap coefficients, and a tap coefficient controller configured to corrects the plurality of tap coefficients in a time division; and a detecting circuit configured to detect a binary data sequence from an output of the equalizer.

In still another aspect of the present invention, an adaptively equalizing method is achieved by equalizing a digital RF signal based on a plurality of tap coefficients; and by correcting each of the plurality of tap coefficients in a time division.

As described above, in the present invention, a plurality of tap coefficients are corrected in time-division, and therefore it is not necessary to provide product-sum operation circuits respectively corresponding to the plurality of tap coefficients. Therefore, according to the present invention, a circuit scale of an adaptive equalizer can be reduced.

### BRIEF DESCRIPTION OF THE DRAWINGS

The above and other objects, advantages and features of the present invention will be more apparent from the following description of certain embodiments taken in conjunction with the accompanying drawings, in which:

FIG. 1 is a diagram illustrating the configuration of a conventional adaptive equalizer;

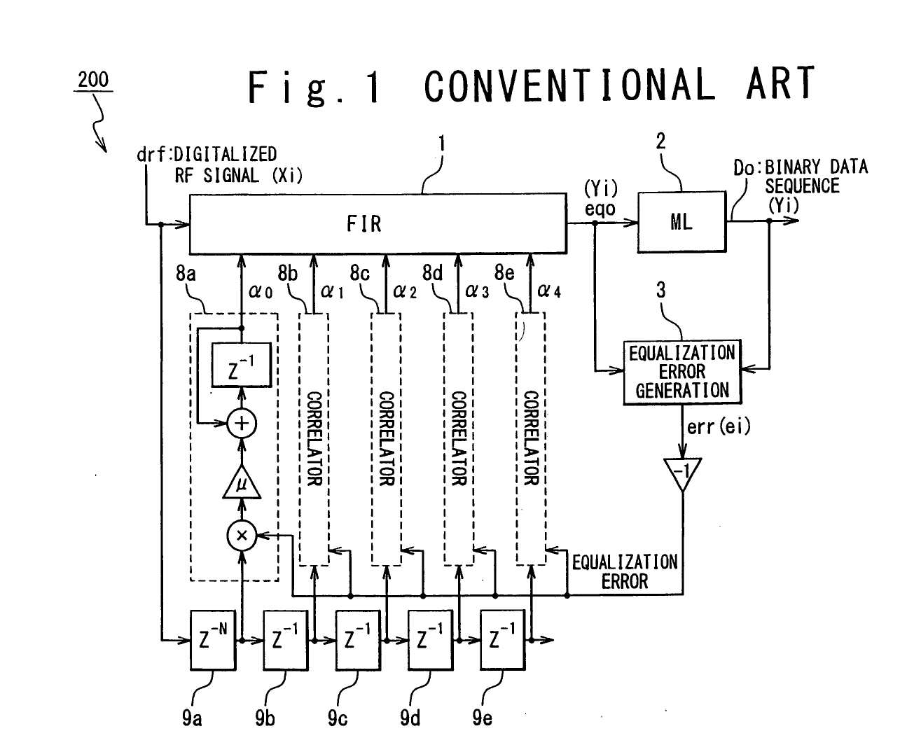

FIG. 2 shows timing charts in a conventional adaptive equalization operation;

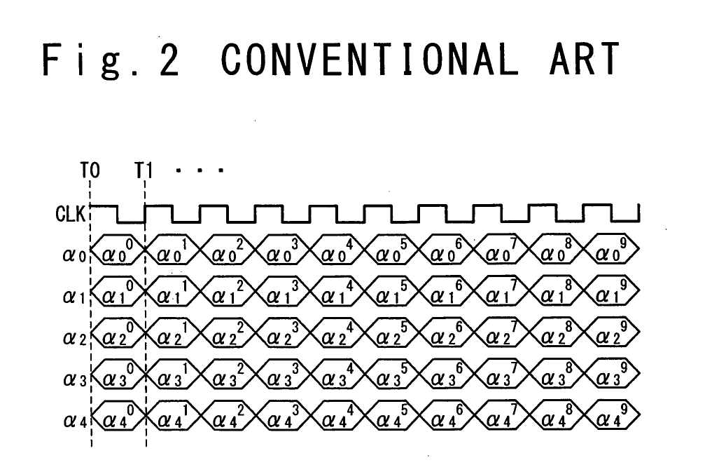

FIG. 3 is a diagram illustrating the configuration of another conventional adaptive equalizer;

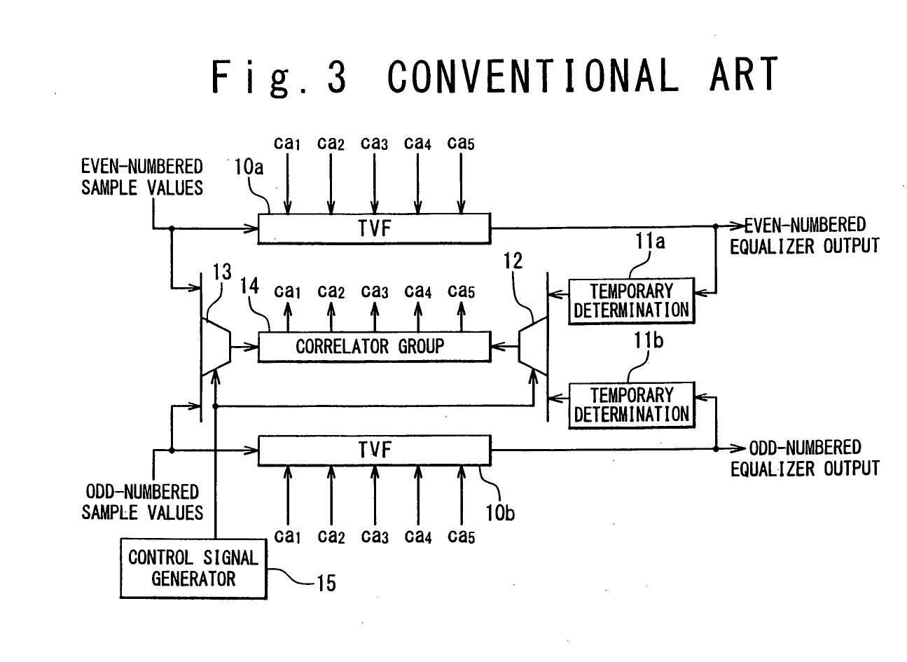

FIG. 4 is a diagram illustrating the configuration of an adaptive equalizer according to an embodiment of the present invention;

FIG. 5 is a diagram illustrating the configuration of a tap coefficient register shown in FIG. 4;

FIG. 6 is a diagram illustrating the configuration of an information reproducing apparatus according to an embodiment of the present invention;

FIG. 7 shows timing charts in an adaptive equalization operation in the embodiment;

FIG. 8 shows timing charts in the adaptive equalization operation in another embodiment; and

FIG. 9 shows timing charts in the adaptive equalization operation in another embodiment.

### DESCRIPTION OF EMBODIMENTS

Hereinafter, an adaptive equalizer of the present invention will be described with reference to the attached drawings. In the drawings, the same or similar reference numerals denote the same or similar components.

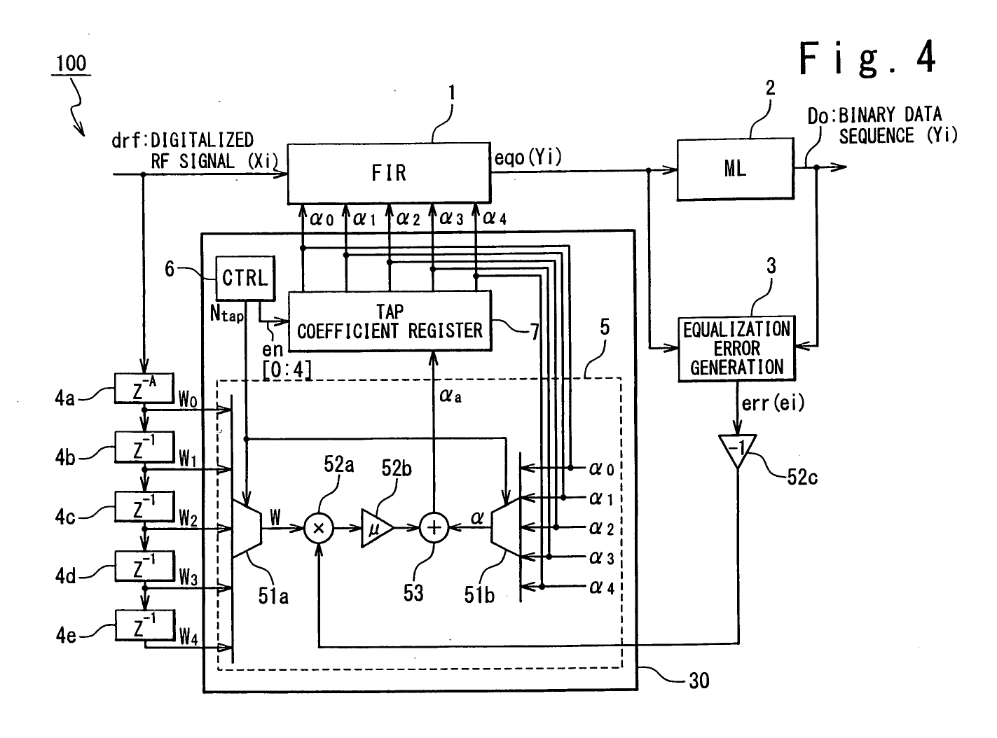

Referring to FIG. 4, a configuration of an adaptive equalizer 100 according to an embodiment of the present invention will be described. FIG. 4 is a diagram illustrating the configuration of the adaptive equalizer according to the embodiment of the present invention. The adaptive equalizer 100 is provided with an equalizer 1, a maximum likelihood detecting circuit 2, an equalization error generating circuit 3, delay circuits 4a to 4e, a product-sum circuit 5, a timing controller 6, and a tap coefficient register 7. A description will be given, taking as an example an adaptive equalizer in which the number of taps is five. However, the number of taps is not limited to this. In addition, preferably, all of the equalizer 1, the maximum likelihood detecting circuit 2, the equalization error generating circuit 3, the delay circuits 4a to 4e, the product-sum circuit 5, the timing controller 6, and the tap coefficient register 7 operate in synchronization with the same clock signal.

The equalizer 1 is preferably a typical N-tap FIR (Finite Impulse Response) filter. In the present embodiment, as the equalizer 1, a five-tap FIR filter (tap coefficients α₀ to α₄) is used. The equalizer 1 is supplied with a reproduction signal (digitalized RF signal drf) obtained from a storage medium such as an optical disc. The digitalized RF signal drf is generated by an A/D converter that samples an RF signal at timing synchronized with the digitalized RF signal drf.

An internal characteristic of the equalizer 1 is the same as that of a typical FIR filter. Supposing that the digitalized RF signal drf at time Tᵢ is Xᵢ, and each of the tap coefficients is αⱼ (j is an integer from 0 to N−1), an output (equalized signal eqo) Yᵢ of the equalizer 1 is expressed by the equation (1), where the number of taps is N. The digitalized RF signal drf is equalized to certain PR characteristics by the equalizer 1, and outputted to the maximum likelihood detecting circuit 2 and equalization error generating circuit 3 as the equalized signal eqo. For example, the digitalized RF signal drf is equalized to a PR(3, 4, 4, 3) channel, and outputted as the equalized signal eqo.

The maximum likelihood detecting circuit 2 detects a binary data sequence Do from the equalized signal eqo on the basis of a predetermined algorithm that selects the most likely state transition. In order to extract PR equalization performance as much as possible, the maximum likelihood detecting circuit 2 preferably performs the Viterbi detection using the Viterbi algorithm. For example, when the digitalized RF signal drf is equalized to the PR(3, 4, 4, 3) channel, the maximum likelihood detecting circuit 2 detects the binary data sequence Do on the basis of the Viterbi detection corresponding to the PR(3, 4, 4, 3) channel.

The equalization error generating circuit 3 calculates an ideal value Ri of an input to the maximum likelihood detecting circuit 2 on the basis of the binary data sequence Do, and outputs a difference between an actual input (equalized signal eqo (Yi)) and the ideal value Ri as an equalization error err (ei). The equalization error err (ei) is expressed by the above equation (2). By convolving a binary data sequence Do of an NRZI (Non Return to Zero Invert) format with impulse response of the PR characteristics, the ideal input (ideal value of the equalized signal eqo) Ri to the maximum likelihood detecting circuit 2 is obtained. The equalization error generating circuit 3 outputs the difference between the ideal input Ri and the actual input to the maximum likelihood detecting circuit 2 (equalized signal eqo (Yi)) as the equalization error err (ei). It should be noted that in consideration of the binary data sequence Do that is largely delayed due to delay inside the maximum likelihood detecting circuit 2, a tentative determination result having a small internal delay may be used for the generation of the equalization error err. The equalization error (ei) is inverted by a multiplier 52c (inverter), and then supplied to the product-sum circuit 5.

The input signal to the equalizer 1, i.e., the digitalized RF signal drf is delayed by the delay circuit 4a by an amount corresponding to the summation of internal delays of the maximum likelihood detecting circuit 2 and equalization error generating circuit 3, and then outputted as a signal W₀ to the product-sum circuit 5. Also, the signal W₀ is further delayed by the delay circuits 4b to 4e connected to the delay circuit 4a in series, and then outputted to the product-sum circuit 5 from them as signals W₁ to W₄. Each of the delay circuits 4b to 4e shifts a phase of a signal inputted thereto every one clock, and then outputs the signal to the product-sum circuit 5 as each of the signals W₁ to W₄.

The product-sum circuit 5 is provided with selectors 51a and 51b, multipliers 52a and 52b, and an adder 53. The selector 51a selects any of the signals W₀ to W₄ inputted through the delay circuits 4a to 4e, and outputs it to the multiplier 52a as a signal W. At this time, the selector 51a determines a signal to be selected as the signal W according to a control signal Nₜₐₚ from the timing controller 6. The multiplier 52a multiplies the signal W selected by the selector 51a by the equalization error err inputted through the multiplier 52c. A result of the multiplication is multiplied by g by the multiplier 52b. Here, g is equivalent to a loop gain in adaptive equalization control. If μ is large, a convergence rate increases, but the control is susceptible to noise. On the other hand, if μ is small, the convergence rate decreases, but the control is resistant to noise. It should be noted that the multiplier 52b is not necessarily configured by use of a multiplier, but can be realized simply with a bit shift register if g is limited to a multiplier corresponding to a power of two.

The selector 51b selects any of the tap coefficients α₀ to α₄ stored in the tap coefficient register 7 to output it to the adder 53 as a tap coefficient α. At this time, the selector 51b selects the tap coefficient α to be outputted to the adder 53 in response to the control signal Nₜₐₚ from the timing controller 6. The adder 53 adds the multiplication result by the multiplier 52b and the tap coefficient α selected by the selector 51b, and outputs the resultant to the tap coefficient register 7 as a corrected tap coefficient αₐ.

The signal pair (W, α) selected by the selectors 51a and 51b is controlled by the control signal Nₜₐₚ from the timing controller 6, and any of (W₀, α₀) (W₁, α₁) (W₂, α₂) (W₃, α₃) or (W₄, α₄) is selected. Also, the timing controller 6 controls a data writing operation into the tap coefficient register 7 based on an enable signal en[0:4], in which a bit number corresponds to the number of taps (N=5 in this case).

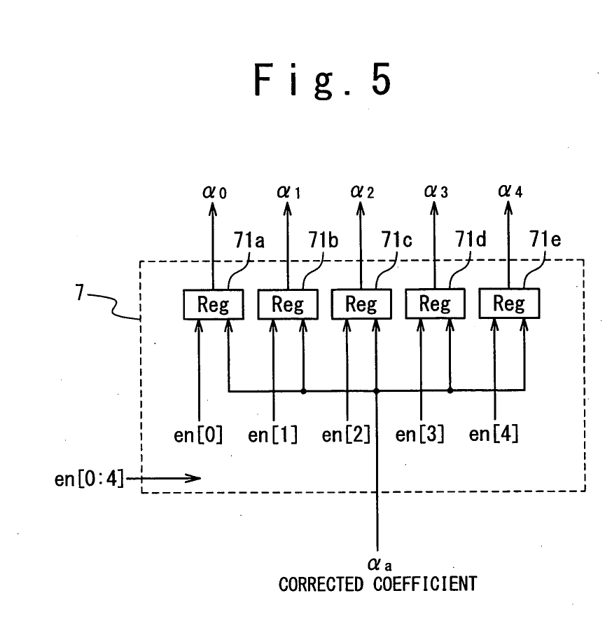

FIG. 5 is a diagram illustrating an example of a configuration of the tap coefficient register 7. The tap coefficient register 7 has registers for the number of taps (N). In the present embodiment, the tap coefficient register 7 has registers 71a to 71e corresponding to the tap coefficients α₀ to α₄. The registers 71a to 71e are connected to the output (corrected tap coefficient αₐ) from the product-sum circuit 5 in common. The respective registers 71a to 71e take in the corrected tap coefficient αₐ according to the corresponding enable signal bits en[0] to en[4]. Specifically, each of the registers 71a to 71e operates in synchronization with the clock. However, only if a corresponding one of individual enable signals is true, a value is updated, whereas in the other cases, a previous value is held. By making any of the five enable signal bits en[0] to en[4] true, only a specific tap coefficient value can be updated.

Also, the enable signal bits en[0] to en[4] may be independently controlled, or a plurality of enable signals may be controlled as a group. For example, by simultaneously setting the enable signal bits en[0] and en[4] and the enable signal bits en[1] and en[3] to be true (high level), the tap coefficients that are symmetrically positioned with respect to the central tap coefficient α₂ can be simultaneously updated to the same value.

As described above, in the adaptive equalizer 100 according to the present invention, the product-sum circuit 5 that is a main component of the correlating circuit is made common to the plurality of taps, and each of the tap coefficients is corrected through the time division operation according to the control by the timing controller 6. Thus, a circuit amount of the adaptive equalizer can be largely reduced. In the present invention, the time division operation makes a coefficient conversion rate to be reduced. However, a rate at which frequency characteristics of the equalization input signal (digitalized RF signal drf) change is small, and therefore after the convergence has completed once, it is not necessary to increase the number of corrections. For this reason, the reduction in rate through the time division operation has a fully allowable magnitude.

It should be noted that the product-sum circuit 5 can be described as a product-sum circuit with an input selection function. Also, the delay circuits 4a to 4e, the product-sum circuit 5, the timing controller 6, and the tap coefficient register 7 can also be collectively referred to as a tap coefficient controller 30.

In the example illustrated in FIG. 4, only one product-sum circuit 5 is provided. However, two or more product-sum circuits may be provided. In such a case, a plurality of tap coefficient registers 7 respectively corresponding to the plurality of product-sum circuits 5 are provided. For example, the total number of taps (N) is halved by two tap coefficient registers 7, and one is controlled by a first product-sum circuit, whereas the other is controlled by a second product-sum circuit. In this way, the convergence rate can be improved, which is reduced through the time division operation. When an the number of product-sum circuits 5A increases, circuit size increases as compared with the example illustrated in FIG. 4. However, if a plurality of tap coefficients are corrected by a common product-sum circuit, the circuit size can be decreased as compared with the conventional case.

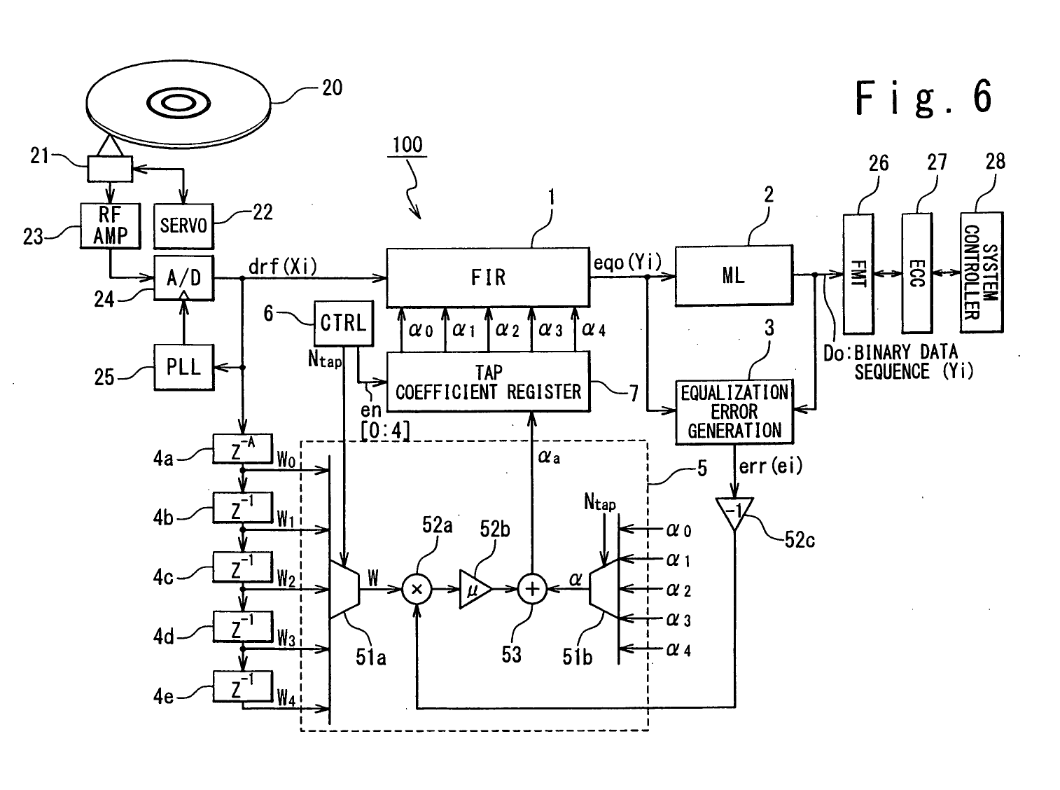

The adaptive equalizer 100 according to the present invention is preferably used for a data reproducing apparatus that obtains and reproduces data from an optical recording medium, or records data on the optical recording medium. FIG. 6 is a diagram illustrating an example of a configuration of a data reproducing apparatus mounted with the adaptive equalizer 100 according to the present invention. The data reproducing apparatus that reproduces data from an optical recording medium 20 will be described as an example.

Referring to FIG. 6, the data reproducing apparatus according to the present invention is provided with the adaptive equalizer 100, an optical pickup device 21, an actuator servo 22, a pre-amplifier 23 (RF AMP), an A/D converter, a PLL (Phase Locked Loop) circuit 25, a formatter 26 (FMT), an ECC demodulator 27 (ECC), and a system controller 28.

The optical recording medium 20 is rotated and controlled by a spindle motor (not shown). From the optical pickup device 21, a focused beam is irradiated toward a record surface of the optical recording medium 20. The actuator servo 22 detects a part of a reflected beam of the collected beam through a photo-detector (not shown) as a tracking signal and a focusing signal, and controls the collected beam to accurately follow a guide groove of the disc. On the other hand, the remaining part of the reflected beam reads fine marks on the disc, and a reproduction signal is extracted through the RF amplifier 23. The reproduction signal passes through an analog filter (not shown), and then is digitalized by the A/D converter 24 with the accuracy of about 6 to 8 bits.

The A/D converter 24 uses a clock generated by the PLL circuit 25 as a sampling clock signal to digitalize the reproduction signal. At this time, the PLL circuit 25 generates the clock signal that is synchronized with the reproduction signal (digitalized RF signal drf). Alternatively, the A/D converter 24 may perform sampling with a system clock signal that is not synchronized with a channel frequency, and then output a synchronized sampling signal to be supplied to the equalizer 1 through digital. PLL and resampling process, as the digitalized RF signal drf.

The digitalized RF signal drf is supplied to the equalizer 1, and then tap coefficients are corrected through the time division operation in the adaptive equalizer 100. A binary data sequence Do that is an output of the maximum likelihood detecting circuit 2 is subjected to frame sync pattern removal and RLL demodulation by the formatter 26. The demodulated data sequence is subjected to error correction processing by the ECC demodulator 27, and then processed in the system controller 28 as data such as video data.

Here, as an apparatus using the adaptive equalizer 100 according to the present invention, the data reproducing apparatus that extracts data from the optical recording medium 20 (optical disc) has been described. The present invention is preferable for an HDD, an optical disc device, and in particular, a data detecting device such as a BD (Blu-ray Disc) player. However, the adaptive equalizer 100 according to the present invention can also be used for reproduction processing in an HDD device or a magnetic tape apparatus, or a receiver for general baseband transmission.

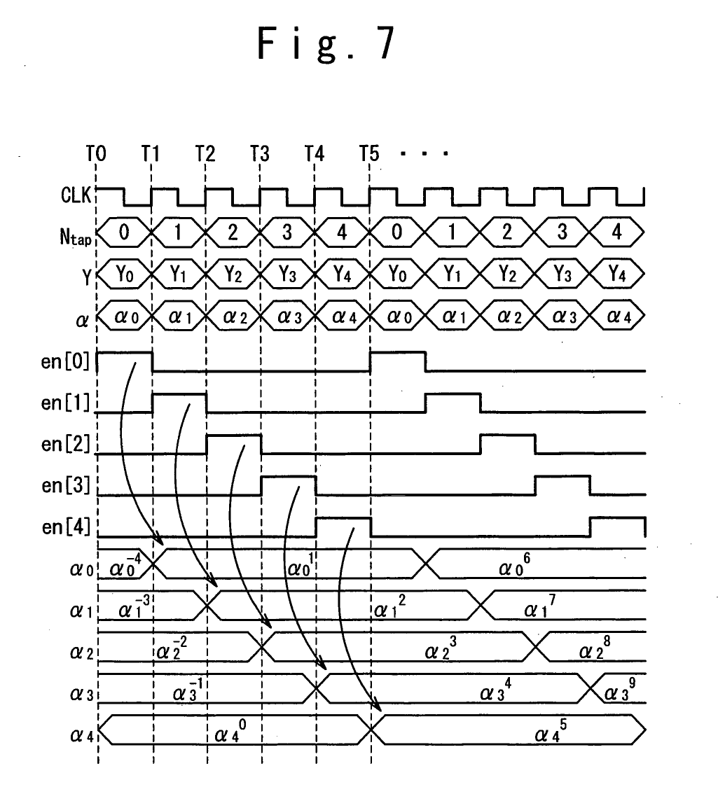

Referring to FIG. 7, an operation of the adaptive equalizer according to the present invention will be described. FIG. 7 shows timing charts in the adaptive equalization operation.

The timing controller 6 controls signal levels of the enable signal bits en[0] to en[4] in synchronization with a clock signal CLK. That is, the timing controller 6 switches to set any of bits of the enable signal en to a high level for each trigger edge of the clock signal CLK, and outputs a control signal Nₜₐₚ corresponding to a tap coefficient to be corrected. In the example illustrated in FIG. 7, at each time synchronous with the clock signal CLK, only one enable signal bit is set to the high level, and the other enable signal bits are set to a low level. Thus, only one tap coefficient is corrected at each time. It should be noted that the tap coefficient α to be corrected is switched in the order of α₀, α₁, α₂, α₃, and α₄ by the selector 51b. Specifically, at time T1, the tap coefficient α₀ (αₒ) that is selected as a correction target is corrected to α₀¹ according to the enable signal bit en[0] having a true value. At the next time T2, the tap coefficient α₁ (α₁⁻³) that is selected as a correction target is corrected to α₁² according to the enable signal bit en[1] having a true value. Similarly, at respective times T3 to T5, the tap coefficients α₂⁻² to α₄⁰ are corrected to α₂³ to α₄⁵. Thus, according to the present example, all of the tap coefficients α₀ to α₄ are corrected in five clocks.

In the conventional technique, the tap coefficients are corrected by the correlating circuits for the number of taps (e.g., five). For this reason, all of the tap coefficients can be corrected in one clock. On the other hand, in the present invention, the tap coefficients are corrected through the time division by use of one product-sum circuit. For this reason, a tap coefficient convergence time in the present invention becomes longer than the conventional case. However, the time variation in frequency characteristics of the input signal (digitalized RF signal drf) is minute, and therefore an influence on normal reproduction performance due to a reduction in convergence performance is small. Thus, according to the present invention, without reducing the normal reproduction performance, a circuit size of an adaptive equalizer can be reduced.

In the example illustrated in FIG. 7, a tap coefficient to be corrected is switched through the cyclic time division operation such that the correction is repeated in the predetermined order. At this time, if the input signal (digitalized RF signal drf) is a singular signal having a period equal to an integral multiple of a tap coefficient correction timing period, a correlation is generated due to such a periodic property, and a tap coefficient may not be converged well. In some cases, a coefficient is diverged or converged to zero. In particular, in a medium in which randomization processing on data is not performed as in a CD format, such a problem may occur.

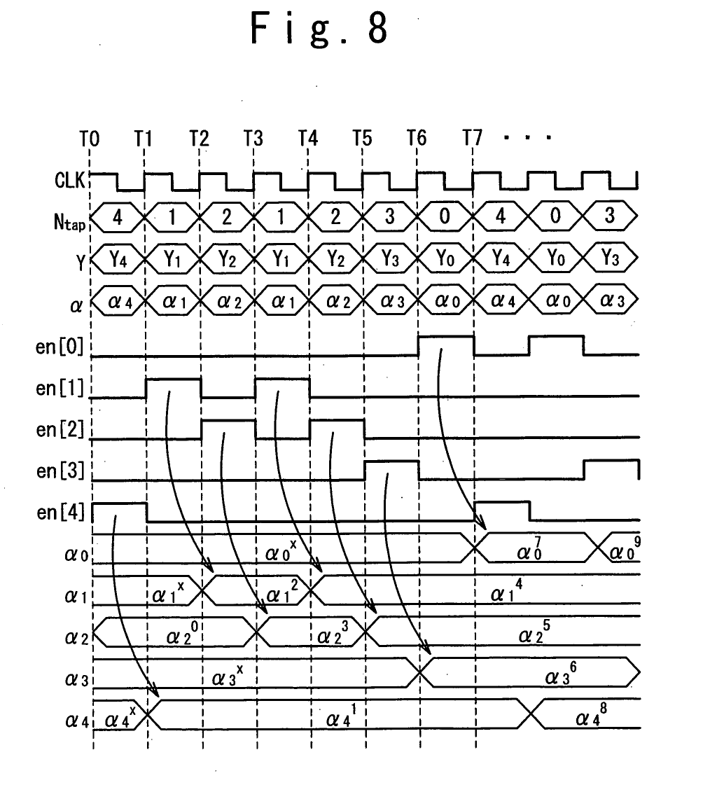

For this reason, in order to solve the above problem, it is effective to provide a random number generator in the timing controller 6 to break the periodic property of the tap coefficient correction order. That is, the timing controller 6 controls the signal levels of the enable signal bits en and the control signal Nₜₐₚ to randomly change a tap coefficient to be corrected. For example, as illustrated in FIG. 8, the tap coefficients to be corrected are randomly switched at times T1 to T7 as α₄, α₁, α₂, α₁, α₂, α₃, α₀, . . . , and at the respective times, the corrections are performed as α₄^{x} to α₄¹ α₁² to α₁⁴ (time T4), α₂³ to α₂⁵ (time T5), α₃^{X} to α₃⁶ (time T6), α₀^{x} to α₀⁷ (time T7), and so on (where x is an randomly selected integer). As described, the tap coefficients α are randomly corrected, and thereby the correlation depending on the periodic property of the input signal (digitalized RF signal drf) can be eliminated to avoid the above problem. The random number generator can be realized with a very small circuit by using an M sequence generator including a feedback shift register, or the like.

As described above, in the present invention, the tap coefficients are corrected through the time division operation, and therefore the tap coefficient convergence rate is reduced. On the other hand, if value of the multiplication factor μ of the multiplier 52b is increased, the tap coefficient convergence rate can be improved. However, in such a case, the tap coefficient is likely to be influenced by noise, and therefore stability of it is lost. On the other hand, if a waveform distortion due to TAN tilt or the like is small, converged tap coefficients are ideally symmetrical with respect to the central tap. For this reason, by simultaneously correcting the tap coefficients αₒ to α₄, i.e., the plurality of taps that are symmetrical with respect to the central tap (tap coefficient α₂), stabilities of the tap coefficients can be ensured. For example, when the number of taps is N (N is an odd number in this case), an i^{th} tap coefficient αᵢ is corrected simultaneously with an [N−(i−1)]^{th} tap coefficient α_{N-(i-1)} that is positioned symmetrically with respect to the central tap. Also, when the number of taps is N (N is an even number in this case), an i^{th} tap coefficient αᵢ is corrected simultaneously with an [N−(i−2)]^{th} tap coefficient α_{N-(i-2)} that is positioned symmetrically with respect to the central tap.

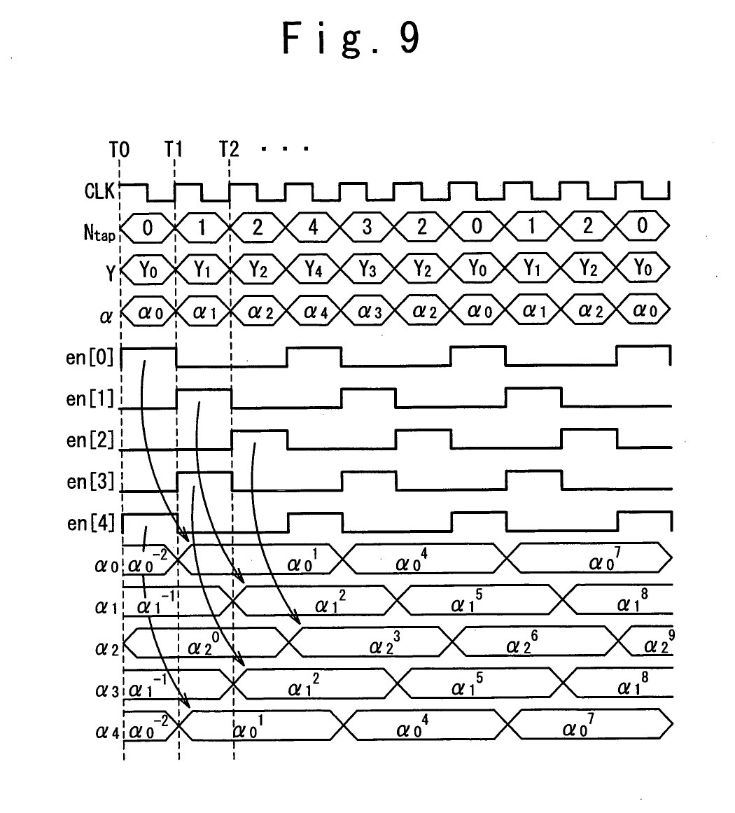

Accordingly, by setting the multiplication factor μ of the multiplier 52 to a large value and symmetrically correcting the tap coefficients, the tap coefficient convergence rate can be improved so as to be hardly influenced by noise. An example of tap coefficient correcting operation for this case is illustrated in FIG. 9.

In the example illustrated in FIG. 9, the timing controller 6 controls the enable signal bits en[0] and en[4] to the same signal level, and the enable signal bits en[1] and en[3] to the same signal level. The timing controller 6 simultaneously corrects the tap coefficients α₀ and α₄ (time T1), then simultaneously corrects the tap coefficients α₁ and α₃ (time T2), and subsequently corrects the tap coefficient α₂ (time T3). After that, the same procedure is repeated, and the tap coefficients are corrected until the tap coefficients α₀ to α₄ are converged. In the example illustrated in FIG. 7, five clocks are required to correct all of the tap coefficients α₀ and α₄. However, in the example illustrated in FIG. 9, the corrections can be made only with three clocks, and therefore the tap coefficient convergence rate can be improved.

From the view of the tap coefficient stability, the tap coefficient convergence rate may be preferably temporarily improved. For example, in an optical disc device, there is the case where data is desired to be reproduced as quickly as possible immediately after the seek. In this case, there is preferably a function that temporarily increases the convergence rate of the adaptive equalizer 100. For this reason, the timing controller 6 is switched to symmetrical tap control (mode in which tap coefficients are symmetrically corrected) as illustrated in FIG. 9 only at the time of fast data acquisition (e.g., immediately after the seek), and in the other periods, performs correction control (normal operation mode in which tap coefficients are sequentially corrected one by one) as illustrated in FIG. 7 or 8. For example, during a certain period immediately after the seek, by increasing μ and correcting tap coefficients on the basis of the symmetrical tap control, and then by restoring the control to the normal operation, the convergence rate can be temporarily increased,

As described above, according to the present invention, the product-sum circuit that is a main component of the correlating circuit is made common to the plurality of taps, and therefore a circuit amount of the adaptive equalizer can be largely reduced as compared with the conventional case. That is, the present invention can reduce a circuit scale of an adaptive equalizer having an equalizer with a large number of taps. Also, a scale of a circuit that operates when tap coefficients are corrected is reduced, and therefore a power consumption amount of an adaptive equalizer, or a data reproducing apparatus using it can be reduced.

Also, the variation in frequency characteristics of the equalization input signal (digitalized RF signal drf) is gradual, and therefore after the first convergence, even in the case of the coefficient corrections through the time division operation, the tap coefficients can be corrected with following the signal variation.

Further, by correcting the tap coefficients in a random order, the correlation between the period of the time division operation and the input signal having the periodic property can be eliminated. For this reason, unstable operation such as divergence or zero convergence of a tap coefficient can be avoided. That is, even for any signal, stable adaptive control can be performed.

As above, the embodiments of the present invention have been described in detail. However, a specific configuration is not limited to the above-described embodiments, but any modification without departing from the scope of the present invention is included in the present invention. The methods for correcting tap coefficients illustrated in FIGS. 7 to 9 may be combined within a technically feasible range. In such a case, any of the correction timings illustrated in FIGS. 7 to 9 may be switched at arbitrary timing to correct tap coefficients.

What is claimed is:

1. An adaptive equalizer comprising:
an equalizer configured to equalize a digital RF signal based on a plurality of tap coefficients; and
a tap coefficient controller configured to correct said plurality of tap coefficients in a time division.

2. The adaptive equalizer according to claim 1, wherein said tap coefficient controller comprises:
a tap coefficient register configured to hold said plurality of tap coefficients; and
a product-sum calculating circuit configured to correct at least one selected from said plurality of tap coefficients in response to an enable signal, by a predetermined product-sum calculation, and update the selected tap coefficient by the corrected tap coefficient.

3. The adaptive equalizer according to claim 2, further comprising:
a plurality of delay circuits configured to said digital RF signal by different delay amounts to generate a plurality of delay signals,
wherein said product-sum calculating circuit corrects one of said plurality of tap coefficients which corresponds to one selected from said plurality of delay signals to generate the corrected tap coefficient.

4. The adaptive equalizer according to claim 2, further comprising:
a maximum likelihood detecting circuit configured to detect a binary data sequence from an output of said equalizer; and
an equalization error generating circuit configured to generate an error between the output of said equalizer and said binary data sequence,
wherein said product-sum calculating circuit corrects the selected tap coefficient through the calculation by use of said error.

5. The adaptive equalizer according to claim 2, further comprising:
a timing controller configured to control the selection of the tap coefficient which is corrected by said tap coefficient controller and output said enable signal to control a correction timing of the tap coefficient.

6. The adaptive equalizer according to claim 5, wherein said timing controller comprises a random number generating circuit, and determines a correction order of said plurality of tap coefficients by the output of said random number generating circuit.

7. The adaptive equalizer according to claim 5, said timing controller controls said enable signal such that two or more of said plurality of tap coefficients are not corrected at a same time.

8. The adaptive equalizer according to claim 7, wherein said timing controller controls said enable signal such that two or more on symmetrical positions of said plurality of tap coefficients with respect to the tap coefficient on a central position are corrected at a same time.

9. The adaptive equalizer according to claim 7, wherein said timing controller has a first mode to control said enable signal such that one from said plurality of tap coefficients is selected and is corrected in the time division, and a second mode to control said enable signal such that two or more of said plurality of tap coefficients are selected and are corrected at the same time.

10. An information reproducing apparatus comprising:
an A/D (analog-to-digital) converter configured to convert a reproduction signal read from an information storage medium into a digital RF signal;
an adaptive equalizer which comprises:
an equalizer configured to equalize said digital RF signal based on a plurality of tap coefficients, and
a tap coefficient controller configured to corrects said plurality of tap coefficients in a time division; and
a detecting circuit configured to detect a binary data sequence from an output of said equalizer.

11. An adaptive equalization method comprising:
equalizing a digital RF signal based on a plurality of tap coefficients; and
correcting each of said plurality of tap coefficients in a time division.

12. The adaptive equalization method according to claim 11, wherein said correcting comprises:
selecting at least one from said plurality of tap coefficients in response to an enable signal;
correcting the selected tap coefficient through a predetermined product-sum calculation; and
updating said plurality of tap coefficients with the corrected tap coefficient.

13. The adaptive equalization method according to claim 11, wherein said correcting comprises:
determining a correction order of said plurality of tap coefficients based on random numbers.

14. The adaptive equalization method according to claim 11, wherein said correcting comprises:
correcting two or more of said plurality of tap coefficients at a same time.

15. The adaptive equalization method according to claim 14, wherein said correcting comprises:
correcting two or more tap coefficients on symmetrical positions of said plurality of tap coefficients with respect to the tap coefficient of a central position at a same time.

16. The adaptive equalization method according to claim 14, wherein said correcting comprises:
switching a first mode in which each of said plurality of tap coefficients is selected and corrected in a time division, and a second mode in which two or more of said plurality of tap coefficients are correct at a same time.

17. An adaptive equalizer comprising:
an equalizer configured to equalize a digital RF signal based on a predetermined number of tap coefficients; and
a tap coefficient controller configured to correct at least one of the predetermined number of tap coefficients which is less than the predetermined number of tap coefficients at a time without correcting remaining tap coefficients.
